(19) United States
(12) Patent Application Publication
(10) Pub. No.: US 2009/0102023 A1
(43) Pub. Date: Apr. 23, 2009

(54) Method for Manufacturing a Structure, Semiconductor Device and Structure on a Substrate

(76) Inventors: Stephan Wege, Dresden (DE); Chirstoph Noelscher, Nuernberg (DE); Alfred Kersch, Putzbrunn (DE); Hocine Boubekeur, Dresden (DE); Christoph Ludwig, Langebrueck (DE)

Correspondence Address: SLATER & MATSIL, L.L.P., 17950 PRESTON ROAD, SUITE 1000, DALLAS, TX, 75252, US

(21) Appl. No.: 11/875,140

(22) Filed: Oct. 19, 2007

(51) Int. Cl. H01L 29/06; H01L 21/31; H01L 21/311

(52) U.S. Cl. 257/626; 438/14; 438/694; 438/758; 257/E21.24; 257/E21.249; 257/E29.005

(57) ABSTRACT

One possible embodiment is a method for manufacturing a structure on a substrate which can be used in the manufacturing of a semiconductor device, including the steps of: forming a first structure on the substrate having at least one sidewall, forming at least one layer as a second structure selectively on the at least one sidewall of the first structure by an epitaxial technique, electroplating, selective silicon dioxide deposition, selective low pressure CVD or an atomic layer deposition technique. Furthermore semiconductor devices, uses of equipment and structures are covered.

### BACKGROUND

In the manufacturing of structures, e.g., on substrates used in the manufacturing of semiconductor devices, it is sometimes necessary to produce liners to sidewalls.

### BRIEF DESCRIPTION OF THE DRAWINGS

In the following drawings, the embodiments of the invention are described as non limiting examples, wherein

FIG. 1 shows a schematic cross section of a substrate with a first structure (first process step for a first embodiment);

FIG. 2 shows a schematic cross section of the substrate with a layer applied to a sidewall of the first structure (second process step of the first embodiment);

FIG. 3 shows a schematic cross section of the substrate before a further processing (third process step of the first embodiment);

FIG. 3A shows a schematic cross section of the substrate after a first step of the further processing;

FIG. 4 shows a schematic cross section of a substrate with a first structure and a passivating layer (first process step for a second embodiment);

FIG. 5 shows a schematic cross section of the substrate with the first structure and second structure and a passivating layer (second process step for a second embodiment);

FIG. 6 shows a schematic cross section of a substrate of a third embodiment in which the substrate is modified with an ion implantation;

FIG. 7 shows a schematic cross section of the substrate of the third embodiment with modified regions;

FIG. 8 shows a schematic cross section of the substrate of a third embodiment with a first and second structure; and

FIG. 9 shows a schematic cross section of a multilayered second structure of a fourth embodiment.

### DETAILED DESCRIPTION OF ILLUSTRATIVE EMBODIMENTS

In the following different embodiments of the invention are described in the context of the manufacturing of semiconductor devices. Examples for semiconductor devices are memory chips such as DRAM chips, PC RAM chips or Flash-memory chips. Furthermore, microprocessors, integrated circuits, optoelectronic devices, microelectromechanical devices or biochips are examples for semiconductor materials.

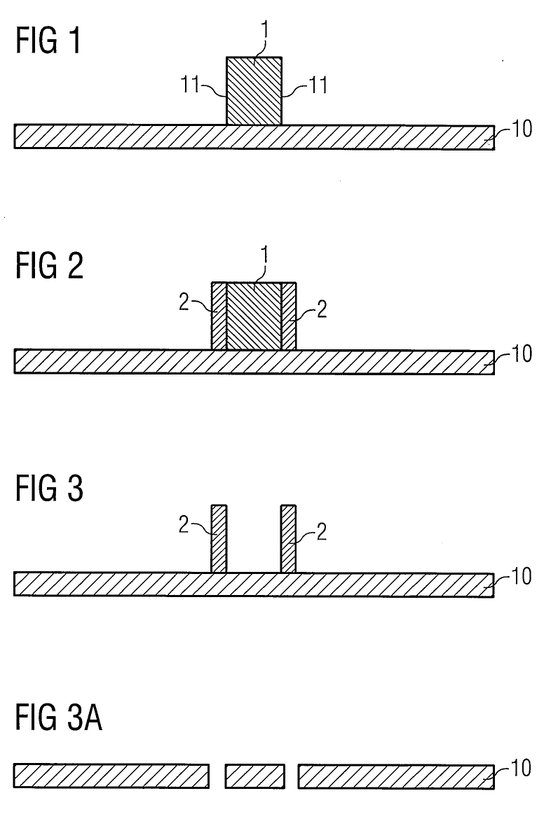

In FIG. 1 a first structure 1 is formed on a substrate 10. The substrate 10 can be, e.g., a silicon wafer, a germanium wafer or a wafer comprising III-V material. It should be noted that the substrate 10 can comprise some structures before the embodiment of the invention is applied to the substrate. For the sake of clarity, the substrate 10 in FIG. 1 is shown without a previous structure, a fact that need not be the case.

On the surface of the substrate 10, a first structure 1 is formed. The first structure 1 comprises two sidewalls 11. In the present embodiment, the first structure 1 is assumed to be a structure projecting into a direction not shown in the FIG. 1, e.g., a linear structure or a ridge. The person skilled in the art will recognize that this is just an example for a first structure. In other embodiments the first structure can be a ridge with a more complex shape or an assembly of patterns.

In FIG. 2 the first structure 1 according to FIG. 1 is shown after the selective forming of second structures 2 on the sidewalls 11 of the first structure 1. The sidewalls of the first structure 1 and thus the two layers 2 are here essentially vertical, i.e., the sidewalls are essentially vertical subject to usual manufacturing constraints.

In other alternative embodiments it is possible that the second structures 2 are not essentially vertical to the substrate, i.e., they are positioned at an angle.

The second structure 2 is formed by the use of atomic layer deposition (ALD), selective silicon dioxide formation (growth and/or deposition), selective low pressure CVD or an epitaxial technique. As epitaxy techniques, e.g., molecular beam epitaxy (MBE) or vapor phase epitaxy can be used. The second structure, e.g., grows epitaxially or is, e.g., deposited in very thin layers.

One way to achieve the second structure 2 is to provide a seed layer (not shown) on the first structure 1. The seed layer enables the growth of a material on the first structure 1. This material can be removed from the top portion of first structure 1, e.g., by an anisotrop irradiation with light, etching and/or reactions with plasma. Another possibility to remove the material from the top portion of the first structure 1 is the use of a CMP process step. A spacer etching can also be performed.

The second structure 2 can be at least one of the group of hafnium, hafnium compounds, hafnium oxide germanium, silicon, titanium, titanium compounds, titanium nitride, zirconium compounds, and/or zirconium oxide.

In case ALD is used, the thickness of the second structure 2 on the sidewall can be adjusted very precisely. Furthermore, the ALD can be used in a pulsed mode, which also enhances the process control. Since many ALD processes are operated in a cyclical mode, the repeated deposition of very thin layers can be achieved.

With these methods, it is possible to form the second structures only on the sidewalls 11 of the first structures 1 and not, e.g., on the substrate 10 or on top of the first structure 1.

In other embodiments, the second structures 2 can be very thin, for example, having a thickness between 1 to 50 nm.

The selectivity can be influenced by the choice of material of the substrate 10, the first structure 1 and the second structure 2. Different methods for creating a selectivity will be discussed below.

After the formation of the second structure 2, the substrate 10 and/or the first structure 1 can be further processed. In FIG. 3 one example of such a step is shown, in which the first structure 1 is removed, e.g., by an etch process. This leaves two second structures 2 on the substrate 10. Since the second structures are very small in width, they can be used as masks to form sublithography structures in further process steps.

In FIG. 3A an example for the result after a first step of the further processing is shown. The second structure 2 has been transferred into the substrate 10. The person skilled in the art will recognize that the form of the second structure 2 is here just exemplary since other structures might be generated. This example for the further processing also applies analog to the other embodiments further described below in.

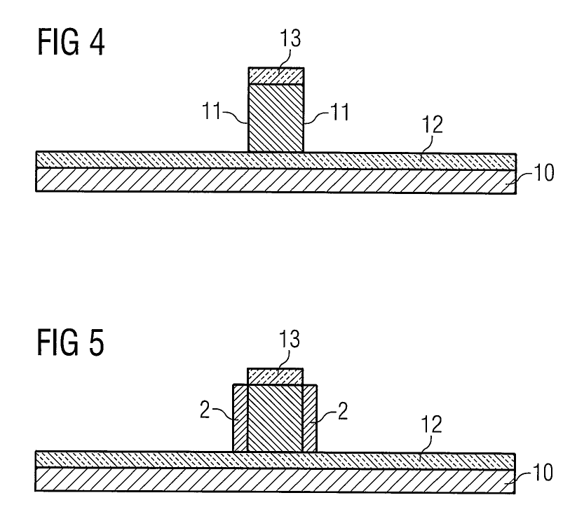

FIG. 4 shows a starting point for a second embodiment of the method. Similar to FIG. 1, a first structure 1 is formed on the substrate 10. The regions not covered by the first structure 1 and underneath the first structure 1 are covered by a passivating layer, here a hard mask layer 12, e.g., made from carbon or SiON. A capping layer 13 made from carbon or Si₃N₄ is formed on top of the first structure 1.

The material 12, 13 is introduced so that the sidewalls 11 of the first structure 1 can be selectively covered with a second structure 2, e.g., by selective oxidation in case of use of SiON and Si₃N₄ layers for layers 12 and 13. In FIG. 5, the structure of FIG. 4 is shown with the additional lining of the sidewalls 11 with the second structure 2.

In a third process step, not shown here, the passivating layer 12 and the capping layer 13 are removed in the open areas that are not covered by the carrier 1 and the further processing might resume as shown, e.g., in FIG. 3. In other embodiments the passivating layers 12, 13 will be stripped off at a later stage after they have been used in the further processing. In another embodiment the capping layer 13, e.g., Si₃N₄, is removed selectively to the layer 12, e.g., SiON and the sidewall layer 2, e.g., SiO₂.

The passivating layer 12, 13, e.g., comprises a siloxan such as Octadcyltrichlorsilan CH₃(CH₂)₁₇SiCl₃. This material is, e.g., passive against ALD processes since the CH-chain molecule is not reactive (i.e., deposition rate is lower). Other materials which can be used alone or in combination with others are Polymers with CH-chains (e.g., Polyethylene) or CF-chains.

The use of passivating layers 12, 13 is just one example of modifying the first structure 1 and the substrate 10 (as shown in FIG. 1) to allow the selective formation of the second structure.

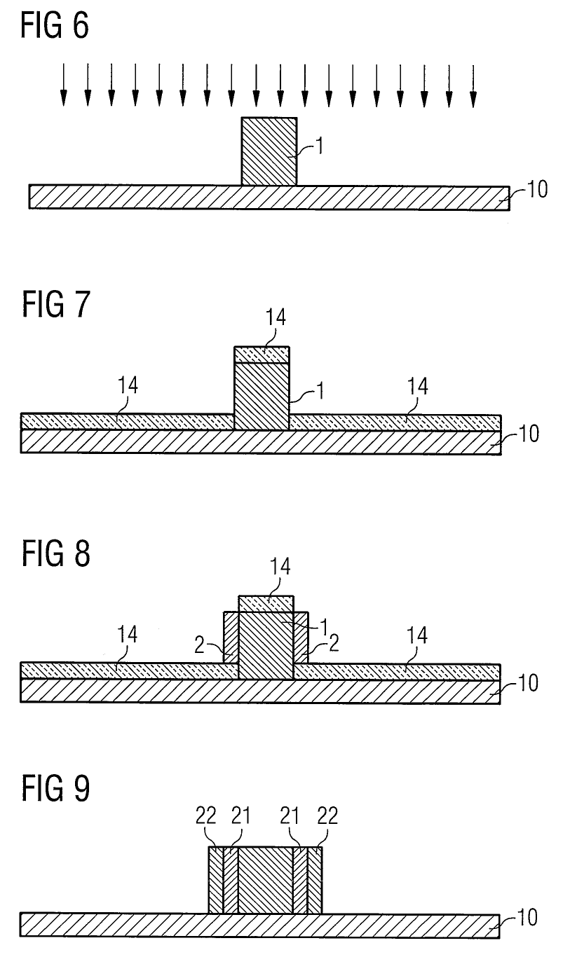

In another embodiment, shown in FIG. 6, the surface of a first structure 1 on a substrate 10 is implanted with, e.g., ions, thereby modifying the surface. This modification yields horizontal regions 14 (see FIG. 7) of the surface which have a lower rate of deposition or growth of the second structure 2 on the sidewalls 11 of the first structure 1.

In FIG. 8 it is then shown, that a second structure 2 is formed on the sidewalls of the first structure 1 selectively.

In the preceding Figures the second structure comprises one single layer.

In another embodiment (see FIG. 9), which can otherwise use any of the process flow as depicted above, the vertical second structures 2 comprise more than one layer, i.e., vertical layer 21, 22. The layer can be from the same material or from different material.

The second structures 2 in the embodiments above (e.g., in FIG. 3 or FIG. 9) might be spacer structures which can be used in pitch fragmentation or spacer techniques. Using these techniques it is possible to manufacture small structures that are arranged on pitches below the effective resolution of the used lithography process, which are labeled as “sublithographic”. Further, the width of such structures may be determined with high precision by the thickness.

The person skilled in the art will recognize that the pitch fragmentation techniques can be used more than once in an area leading to higher order pitch fragmentations, i.e., ever smaller structures can be manufactured. Furthermore, it is possible to exploit different selectivities between materials to define combinations of regions or subregions to define the pattern to be transferred into the substrate.

In addition the person skilled in the art will recognize that the embodiments of the pitch fragmentation techniques can be modified in many ways and can be used in different combinations and with all kind of materials. The principles of the pitch fragmentations are not exhaustively covered by the examples given here.

In the present description of different embodiments, the term process step was used. The person skilled in the art will note that term process step can comprise more than one particular processing, e.g., etching. As was indicated in the description above sometimes more then one sub-steps were described together as one process step. Furthermore, it is clear that between two process steps other processes or sub-steps might be applied.

Furthermore, the different process steps in the embodiments described are exemplary. The person skilled in the art will recognize that individual process steps of one embodiment can be combined with individual process steps from another embodiment.

What is claimed is:

1. A method for manufacturing a structure on a substrate which can be used in the manufacturing of a semiconductor device, the method comprising:
forming a first structure on the substrate having at least one sidewall;
selectively forming at least one layer as a second structure on the at least one sidewall of the first structure, the selectively forming being performed using an epitaxial technique, electroplating, selective silicon dioxide deposition, formation by selective low pressure CVD or an atomic layer deposition technique; and
performing further processing of the substrate or the first structure.

2. The method according to claim 1, with the epitaxial technique is at least one of molecular beam epitaxy and vapor phase epitaxy.

3. The method according to claim 1, wherein the at least one second structure is at least in parts a spacer structure.

4. The method according to claim 3, wherein the spacer structure is used in further processing steps to form structures in the substrate.

5. The method according to claim 4, wherein the structures in the substrate are sublithographic structures.

6. The method according to claim 3, wherein the spacer is used in a pitch fragmentation technique.

7. The method according to claim 1, further comprising forming a hardmask layer over the substrate before forming the first structure.

8. The method according to claim 7, wherein a hardmask layer comprises carbon, SiON, Si₃N₄, aluminum, tungsten, polysilicon, tungsten nitride, aluminum nitride, TiSi, TaSi or Al₂O₃.

9. The method according to claim 1, further comprising modifying regions of the first structure and/or the substrate before the forming of the second structure so that material of the second structure is not deposited on the modified regions.

10. The method according to claim 9, wherein modifying comprises performing at least one of irradiation, ion implantation or the formation of a passivating layer.

11. The method according to claim 10, wherein the first structure comprises a nitride layer altered by irradiation or implantation, the method further comprising performing an oxidation in the region with the altered properties.

12. The method according to claim 9, wherein modifying comprises forming a passivating layer, the passivating layer comprising a siloxan, a polymer comprising CH-groups and/or a polymer comprising CF-groups.

13. The method according to claim 9, wherein modifying comprises capping at least parts of the first structure.

14. The method according to claim 1, wherein the at least second structure is formed with a pulsed technique.

15. The method according to claim 14, wherein the pulsed technique comprises an atomic layer deposition technique.

16. The method according to claim 1, further comprising measuring a thickness of the at least one second structure in-situ.

17. The method according to claim 1, wherein the second structure comprises at least one material selected from the group consisting of hafnium, hafnium compounds, hafnium oxide germanium, silicon, titanium, titanium compounds, titanium nitride, zirconium compounds, and zirconium oxide.

18. The method according to claim 1, wherein the at least one second structure has a thickness between about 1 and about 50 nm.

19. The method according to claim 1, wherein the method is used to manufacture a semiconductor device, selected from the group consisting of memory chips, DRAM chips, PC RAM chips, Flash chips, microprocessors, optoelectronic devices, microelectromechanical devices and biochips.

20. A semiconductor device manufactured by the method of claim 1.

21. A method of manufacturing a semiconductor device, the method comprising:
forming a first structure over a substrate; and
using an atomic layer deposition system or a molecular beam epitaxy system to selectively form at least one layer as a second structure on at least one sidewall of the first structure.

22. A structure on a substrate obtained by:
forming a first structure over the substrate;
selectively forming at least one layer over at least one sidewall of the first structure, the at least one layer selectively formed by an epitaxial technique, selective silicon dioxide deposition or an atomic layer deposition technique; and
performing further processing of the substrate and/or the first structure.

23. The structure according to claim 22, wherein the at least one layer is used in further processing steps to form structures in the substrate, wherein the structures in the substrate comprise sublithographic structures.

24. An intermediate structure of an integrated circuit comprising a first structure having at least one sidewall and a second structure of a different material, wherein a crystal structure of the first and second structures are continuous over an interface between the first and second structures.

25. A method of manufacturing a semiconductor device, the method comprising:
forming a first structure over a substrate;
selectively forming a second structure over sidewalls of the first structure such that substantially no second structure is formed on a top surface of the substrate or a top surface of the first structure;
removing the first structure; and
processing the substrate by means of the second structure.
